(19) United States
(12) Patent Application Publication
(10) Pub. No.: US 2004/0121069 A1
(43) Pub. Date: Jun. 24, 2004

(54) Repairing defects on photomasks using a charged particle beam and topographical data from a scanning probe microscope

(76) Inventors: David C. Ferranti, Concord, MA (US); Valery Ray, Haverhill, MA (US); Gerald Smith, Nashua, NH (US); Christian R. Musil, New Providence, NJ (US)

Correspondence Address: MICHAEL O. SCHEINBERG, P.O. BOX 164140, AUSTIN, TX, 78716-4140, US

(21) Appl. No.: 10/636,309

(22) Filed: Aug. 7, 2003

Related U.S. Application Data
(60) Provisional application No. 60/402,010, filed on Aug. 8, 2002.

(51) Int. Cl. C23C 14/28

(52) U.S. Cl. 427/140; 427/595; 118/715

(57) ABSTRACT

Topographical data from a scanning probe microscope or similar device is used as a substitute for endpoint detection to allow accurate repair of defects in phase shift photomasks using a charged particle beam system. The topographical data from a defect area is used to create a display of a semitransparent topographical map, which can be superimposed over a charged particle beam image. The density of the topographical image and the alignment of the two images can be adjusted by the operator in order to accurately position the beam. Topographical data from an SPM can also be used to adjust charged particle beam dose for each point within the defect area based upon the elevation and surface angle at the particular point.

The application claims priority from U.S. Provisional Patent Application No. 60/402,010, which was filed Aug. 8, 2002 and which is hereby incorporated by reference.

### FIELD OF THE INVENTION

This invention relates generally to charged particle beam milling and, in particular, to an apparatus and method for repairing defects on photomasks using topographical data from a scanning probe microscope.

### BACKGROUND OF THE INVENTION

One step in the fabrication of integrated circuits entails the use of lithography. A semiconductor substrate on which circuits are being formed is typically coated with a material, such as a photoresist, that changes solubility when exposed to radiation. A lithography tool, such as a mask or reticle, positioned between the radiation source and the semiconductor substrate casts a shadow to control which areas of the substrate are exposed to the radiation. After the exposure, the photoresist is removed from either the exposed or the unexposed areas, leaving a patterned layer of photoresist on the wafer that protects parts of the wafer during a subsequent etching or diffusion process.

The term mask is used generically herein to refer to any lithography tool, regardless of the type of exposing radiation and regardless of whether the image of the mask is printed once or stepped across the substrate. A mask typically comprises a patterned layer of an absorber material, such as chromium or molybdenum silicide, on a substrate, such as quartz.

As semiconductor manufacturers attempt to decrease the size of integrated circuits, the pattern that must be transferred to the surface of the semiconductor substrate must become smaller and more complex. One problem with conventional masks is that diffraction causes the light pattern transmitted throughout the photomask to “blur.” This problem is particularly acute as the line-width reaches sub-micron levels. At these levels, device line-widths are so narrow that conventional light sources and lenses, and/or ordinary photomasks, cannot ensure the designs accurately print on the wafer.

One way to overcome this problem is to use phase shift masks, which are capable of sharpening the light's effects on photoresist for sub-micron designs far better than ordinary masks. Phase shift photomasks may include, in addition to patterned chromium on quartz, complex three-dimensional (3D) reticle enhancement structures that provide a means to change the phase of light passing through different regions of the mask. The variants to 3D-reticle structures include alternating phase shifters—typically an etched region in the quartz substrate—and attenuated shifters—such as a layer of partially transmissive material (typically MoSiON or chrome oxide)—on the quartz substrate.

When any type of photomask is manufactured, it is not unusual for the photomask to have defects. For ordinary (non-phase shift) photomasks there are essentially two defect types, opaque and clear. Clear defects are areas where absorber is missing from areas that should be opaque; opaque defects are areas having absorber material deposited in areas that should be clear. In addition to the clear and opaque defects found in ordinary masks, phase shift photomasks can have defects in the etched substrate itself, such as a bump where excess substrate material is present or a divot or hole in the substrate.

Since any defect in the photomask will prevent the desired pattern from being transferred to the surface of the semiconductor substrate, these defects must be repaired before the photomask can be used. (Clear and opaque defects will themselves be transferred as a part of the pattern; while substrate defects in phase shift photomasks will alter the phase shift of the substrate and adversely affect the quality of the pattern.) One problem with the use of phase shift photomasks is that bump and divot type defects are very difficult to repair. Since the cost of a set of advanced reticles for a semiconductor manufacturing process can approach $1 million, the value of a process capable of repairing these types of defects in phase shift photomasks is obvious.

Charged particle beam systems such as focused ion beam systems (FIB) have traditionally been used to repair defects in photolithography masks. Typically, when an FIB system is used to repair a defect in a photomask, a finely focused beam of gallium ions from a liquid metal ion source is scanned across the photomask surface to form an image of the surface. The intensity at each point of the image is determined by the current of secondary electrons ejected by the ion beam at the corresponding point on the substrate. The defect is identified on the image, and the ion beam is then directed at the defect area in order to remove the excess absorber material from a photomask surface or to deposit missing absorber material (typically by using a gas that decomposes in the presence of the ion beam and deposits material onto the surface.).

When used to remove material, the heavy gallium ions in the focused ion beam physically eject atoms or molecules from photomask surface by sputtering, that is, by a transfer of momentum from the incoming ions to the atoms at the surface. The momentum transfer mechanism is considered to function through a series of collisions with nuclei in the substrate lattice, the process being referred to as a “collision cascade.”

Typically, the use of a charged particle beam system to repair defects on photomasks with minimal damage to the surrounding and underlying quartz substrate requires accurate endpoint detection. Normally, secondary ion mass spectrometry (SIMS) or voltage contrast/gray scale contrast are used to detect a change in the material being milled (referred to as the endpoint). For example, during the repair of an opaque defect (which is defined as opaque absorber material in an area that should be clear) once secondary ion mass spectroscopy no longer detects molecules of the opaque absorber material being ejected from the surface, this indicates that the opaque defect has been removed and the milling process is halted.

However, some types of defects found in phase shift photomasks are not susceptible to this type of endpoint detection. For example, on an alternating aperture phase shift mask with a groove etched into the quartz substrate, the defect might consist of a quartz bump on one of the walls of the quartz groove (in an area where the quartz should have been etched away). Because there is no compositional change between the quartz bump and the substrate, it is difficult to know when to stop milling.

The present invention utilizes detailed data about the topography of a defect as a substitute for accurate endpoint detection and allows this topographical data to be utilized by a charged particle beam device to accurately repair a photomask defect. This topographical data on an extremely small surface such as a quartz bump defect can be collected using a scanning probe microscope (SPM) or similar device.

There are two main families of scanning probe microscopes: the scanning tunneling microscopes (STM) and the atomic force microscopes (AFM). Scanning tunneling microscopes measure the current of electrons traveling between the tip of the scope and the substrate, while atomic force microscopes measure by sensing a magnetic or mechanical force on the sample surface by touching it.

Using an atomic force-type SPM, a highly detailed three-dimensional image of a surface can be obtained by using an extremely small tip, usually etched from silicon, to raster-scan across the surface of a sample. The tip is attached to a cantilever that is deflected as the tip moves up and down in response to peaks and valleys on the sample surface. The deflection of the cantilever is monitored by reflecting a laser beam off the back surface of the cantilever into a photodiode sensor. Changes in the deflection of the cantilever cause changes in the position of the laser beam on the detector. These changes are sensed by a computer that compiles the hills and valleys that make up the image. The tip used by an SPM is ordinarily of nanometer-scale sharpness, allowing the SPM to produce a three dimensional image of surface topography at a resolution reaching sub-nanometer levels, sometimes approaching the atomic or molecular scale.

An atomic force-type SPM can operate in three different modes—contact mode, non-contact mode, and intermittent-contact mode. In contact mode, the tip is in physical contact with the sample surface. In non-contact mode, the tip does not actually touch the sample surface. Instead, the tip is in close proximity to the sample surface and interactive forces between the tip and the surface are measured. And in intermittent-contact mode, the cantilever is oscillated at its resonant frequency (often hundreds of kilohertz) and positioned above the surface so that the tip only taps the surface for a very small fraction of its oscillation period.

For any type of SPM, a piezoelectric scanner (capable of extremely fine movements) typically is used as a positioning stage to accurately position the probe over the sample. The scanner moves the probe across the first line of the scan, and back. It then steps in the perpendicular direction to the second scan line, moves across it and back, then to the third line, and so forth. The path differs from a traditional raster pattern in that the alternating lines of data are not taken in opposite directions. SPM data are usually collected in only one direction to minimize line-to-line registration errors that result from scanner hysteresis.

As the scanner moves the probe along a scan line, the SPM collects data concerning the surface of the sample at equally spaced intervals. The spacing between the data points is called the step size or pixel size. The accuracy of the scan can be increased by using a smaller pixel size (which results in a greater number of data points, also referred to as pixel density). However, scans using a greater pixel density take longer to complete and require more resources to store and process.

In addition to pixel size, the accuracy of a scan is also affected by the shape and size of the tip. In general, a narrow and accurately manufactured probe tip has greater resolution than a broad and crudely manufactured probe tip. A probe tip that is large or blunt can measure very flat surfaces without much loss of information, but such a tip will not be able to trace the true profile of a surface that includes features smaller than the probe tip or surface walls with high sidewall angles. Special, high aspect ratio probe tips with cylindrical shapes and sub-micron diameters have been developed for applications where greater resolution is required. However, these sharper tips are more expensive and less durable.

The use of SPM data to control FIB repairs of photomask defects has long been proposed. However, there have been a number of difficulties to be overcome before such a repair method could be put into actual practice.

First, it is difficult to accurately match up the defect location from the SPM data with the FIB system. When a work piece is transferred from an SPM to an FIB system, the x and y defect coordinates from the SPM data are simply not accurate enough to allow the FIB to repair the defect without some method of fine tuning the defect location. Further, the piezoelectric drivers used in FIB systems have hysteresis that makes the absolute x and y coordinates vary from scan to scan.

Also, even if the defect location can be accurately determined in the FIB system, calculation of the appropriate FIB dose for each point in the defect is somewhat difficult. Since defect areas with different surface angles mill at different rates, an absolute dose/height calculation based solely upon the milling rate for a given material would not be accurate enough to allow satisfactory repairs of real-world defects.

The present invention overcomes these difficulties and allows the use of SPM data to characterize the exact size and shape of a reticle defect and further allows this data to program a scan strategy and corrected beam dose profile to remove the defect. The invention allows the integration of the SPM and FIB technologies to provide a complete reticle repair solution.

### SUMMARY OF THE INVENTION

The present invention comprises methods and apparatus for repairing defects on photomasks, particularly phase shift photomasks. It is an object of the invention to use topographical data from a scanning probe microscope or similar device to allow accurate repair of defects in phase shift photomasks using a charged particle beam system, such as an FIB system.

In accordance with one aspect of the invention, the topographical data from a defect area is used to create a display of a semitransparent topographical map, which can be superimposed over a charged particle beam image. The density of the topographical image and the alignment of the two images can be adjusted by the operator. This allows the topographical data to accurately position the beam and to determine the appropriate beam dose in order to make the desired repair.

In accordance with another aspect of the invention, topographical data from an SPM is used to adjust charged particle beam dose for each point within the defect area based upon the elevation and surface angle at the particular point.

The foregoing has outlined rather broadly the features and technical advantages of the present invention in order that the detailed description of the invention that follows may be better understood. Additional features and advantages of the invention will be described hereinafter. It should be appreciated by those skilled in the art that the disclosure provided herein may be readily utilized as a basis for modifying or designing other structures for carrying out the same purposes of the present invention. Persons of skill in the art will realize that such equivalent constructions do not depart from the spirit and scope of the invention as set forth in the appended claims, and that not all objects attainable by the present invention need be attained in each and every embodiment that falls within the scope of the appended claims.

The subject matter of the present invention is particularly pointed out and distinctly claimed in the concluding portion of this specification. However, both the organization and method of operation, together with further advantages and objects thereof, may best be understood by reference to the following description taken in connection with accompanying drawings wherein like reference characters refer to like elements.

### BRIEF DESCRIPTION OF THE DRAWINGS

For a more complete understanding of the present invention, and the advantages thereof, the following description is made with reference to the accompanying drawings, in which:

FIG. 1 is a cross sectional view of a typical quartz bump defect on a prior art photomask.

FIG. 2 is a flowchart showing the steps of a preferred embodiment of the present invention.

FIG. 3 shows schematically a preferred embodiment of the invention.

FIG. 4A shows an example of a virtual topographical map of a defect area superimposed upon the display of a focused ion beam image using only the x and y coordinates from the SPM scan.

FIG. 4B shows an example of a virtual topographical map of a defect area superimposed upon the display of a focused ion beam image after alignment by the operator.

FIG. 5A shows a representation of a three-dimensional virtual topographical map of a defect.

FIG. 5B shows a representation of a two-dimensional topographical bitmap of a defect.

FIG. 6 shows a representation of a three-dimensional virtual topographical map of a defect illustrating one method of calculating slope angle at each dwell point within the defect area.

FIG. 7 shows a representation of a three-dimensional topographical bitmap illustrating another method of calculating slope angle at each dwell point within the defect area.

FIG. 8 shows a representation of a three-dimensional topographical bitmap illustrating another method of calculating slope angle at each dwell point within the defect area.

### DETAILED DESCRIPTION OF THE PREFERRED EMBODIMENTS

The present invention uses a scanning probe microscope or atomic force microscope to form an image of a photomask defect in three dimensions. Two dimensions of the SPM image (those in the plane of the photomask pattern) are aligned to and superimposed on the image produced by a charged particle beam. The third dimension (height or depth of the defect) from the SPM image is used to control the particle beam dose applied to the defect.

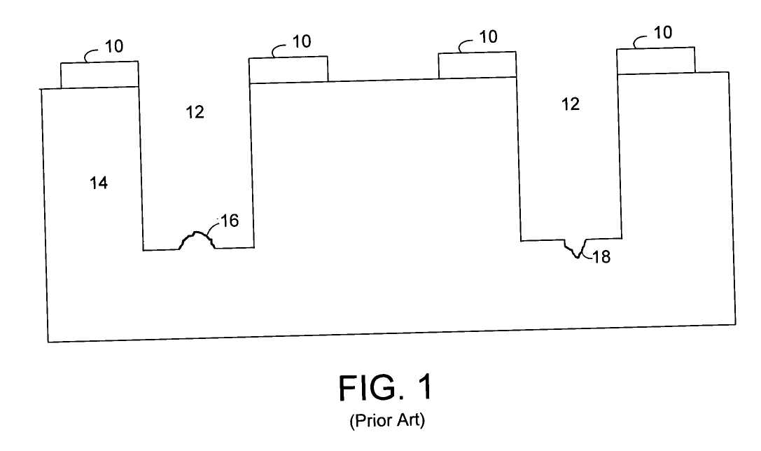

FIG. 1 is a cross sectional view of a typical quartz bump defect and a divot defect on a prior art photomask. FIG. 1 shows opaque material 10, such as chromium, deposited on the substrate 14. In this example, both a bump defect 16 and a divot defect 18 are shown inside phase shift wells 12.

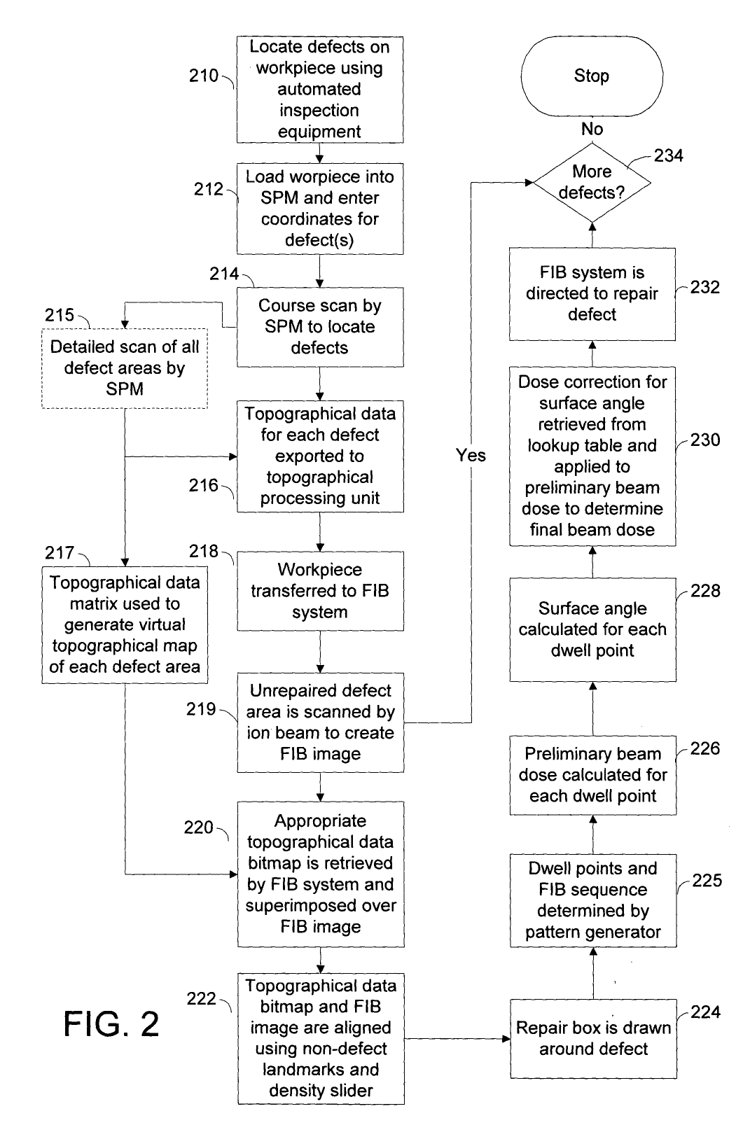

FIG. 2 is a flowchart showing the steps of a preferred embodiment of the present invention used to repair the bump defect 16 in FIG. 1. In step 210, a defect area on the workpiece is located using automatic inspection equipment such as a KLA-351 mask inspection tool. Methods of inspecting phase shift photomasks for defects are taught, for example, in U.S. Pat. No. 6,282,309 to Emery entitled “Enhanced Sensitivity Automated Photomask Inspection System.”

In step 212, the coordinates of the defect area are then supplied to a topographical mapping device such as a scanning probe microscope or similar device capable of providing detailed data as to the topography of the workpiece in the defect area.

In step 214, the defect area is examined by a topographical mapping device, such as the FEI SNP 9000 (Stylus NanoProfilometer) commercially available from FEI Company, Hillsboro, Oreg., the assignee of the present invention A coarse scan by the topographical mapping device is used to locate the defect. This coarse scan would typically scan a 10×10 um area at a lateral resolution of 50 nm and a vertical resolution of 100 nm, although different areas and resolutions can be used depending on the size and type of defect. In a preferred embodiment, the coarse scan would also include topographical data outside of the defect area. The scan should only include enough data from outside the defect area to enable the operator to locate unique topographical features and allow the SPM scan to be aligned with subsequent FIB scans.

If necessary, in optional step 215, the coarse scan can be followed by a more detailed scan of the defect itself. The area and resolution will be determined by the operator based upon the type and size of the defect. Due to the large time and memory requirements of scans at a very high resolution, the operator will typically select the lowest resolution necessary to adequately describe a given defect. The accuracy of the topographical representation can be increased by using a greater number of data points, also referred to as pixel density. However, scans using a greater pixel density take longer to complete and require more resources to store and process. The pixel density required will vary based upon the size and type of defect. Commercially available SPM devices are capable of sub-nanometer resolution.

In step 216, once all necessary SPM scans have been completed, the topographical data is exported to a topographical data processing unit which stores that data, preferably in the form of a matrix that is easy to process.

In step 217, the topographical data is used to generate a virtual topographical map of the surface of the defect area. The virtual topographical map is comprised of lines representing the defect's dimensions in the x and y and the elevation of the various points within the defect as measured by the SPM scan (much like lines on a typical topographical map of a mountainous area of the earth's surface). This virtual topographical map is stored in appropriate computer memory.

In step 218, the workpiece is transferred to an appropriate charged particle beam system, for example a typical focused ion beam system such as an FEI Accura 800 or 850, commercially available from FEI Company, Hillsboro, Oreg., the assignee of the present invention. The work piece is positioned on a stage that is maneuvered, for example, using positional information from the previous automatic inspection equipment, so that the defect is within the area scanned by the ion beam. The term charged particle beam as used herein, encompasses ion beams and electron beams. Moreover, the term charged particle beam shall include ion beams, including gallium ion beams generated by commercially available FIB systems and inert gas (for example, helium and argon) ion beams generated by a gas field ion source (GFIS).

In step 219, the beam scans the surface of the area around the defect to produce an FIB image, which is visually displayed on some type of monitor such as a conventional CRT or flat panel monitor. Typically, the defect area would be scanned using a raster pattern (scanning a series of data points from side to side in lines from top to bottom) although other patterns may be employed. The resolution of the charged particle beam scan is determined by the distance between the data points (and the diameter of the ion beam). The spacing between dwell points of the focused ion beam system is greater than the spacing between measurement points in the SPM. The resolution of the FIB image will typically be much lower than the resolution of the SPM scan, typically from 5 nm to 50 nm. However, in a preferred embodiment the scale of both displayed images are adjusted to be the same. (In other words, for a feature visible in both images, the size of that feature as displayed should be the same.) Information contained in the AFM file indicates the size of the AFM features. This information is used to scale the AFM defect image to the FIB image. Slight miscalibrations between the FIB and the AFM can be corrected in software.

In step 220, the display of the virtual topographical map of the defect area can then be superimposed upon the display of the FIB image. The topographical data is represented by a two dimensional bitmap (showing x and y dimensions) that is superimposed onto the FIB image.

In step 222, the operator exactly aligns the two displayed images using appropriate references, such as features of the mask that are visible in both images and an operator input device. For example, a conventional mouse would allow the operator to select the topographical data bitmap on the display and “drag” the image in order to properly align it with the charged particle beam image. In a preferred embodiment, the density of the topographical data bitmap image can be adjusted by means of a “slider control,” either a physical control or a control on a display screen, to make the image more transparent or less transparent. This semitransparent bitmap can be positioned by means of a mouse so that it is aligned with the corresponding features on the FIB image. Alternatively, the displayed images could be aligned automatically using image recognition software.

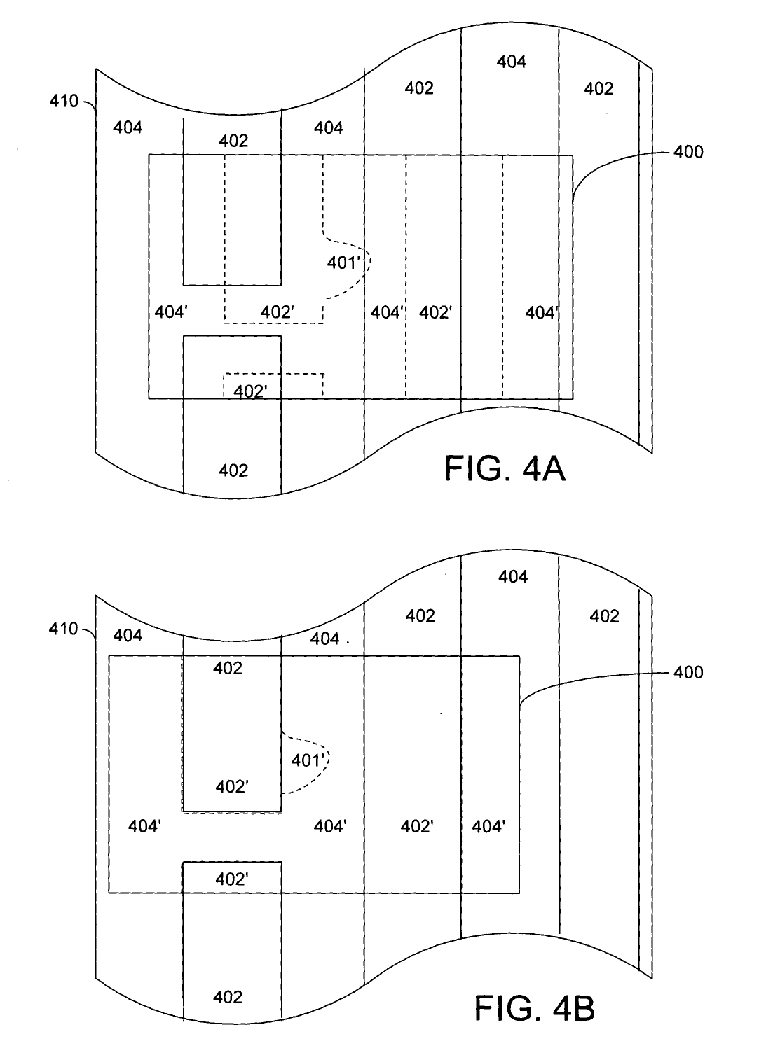

In a preferred embodiment, the topographical data bitmap contains information about the defect as well as information about surrounding non-defect areas. Since many types of defects will not be visible on the FIB image (such as quartz bump defects on phase shift photomasks) the SPM scan can include landmarks from the surrounding non-defect areas which can be used by the operator to accurately align the images. Alignment of the topographical data bitmap with the FIB image is discussed with reference to FIG. 4A and FIG. 4B below. Several adjustments of the transparency of the topographical bitmap may be required for accurate alignment. Less transparency makes it easier to view the defect and landmarks in the topographical bitmap but obscures more of the FIB image; more transparency makes it easier to view the FIB image at the expense of the topographical bitmap. The ability to easily adjust the image density of the topographical bitmap allows the operator to select an optimum value or to move the image density back and forth to ensure that the alignment is correct.

In step 224, once the images have been aligned the operator defines a repair area by drawing a repair box around the defect using a mouse. The repair box should include the entire defect to be repaired. Any non-defect areas included in the repair box will be excluded from the repair process by the maximum and minimum limits in step 226 below.

In step 225, a pattern generator implemented in hardware or software breaks down the area inside the repair box into a sequence of points which are then provided to the ion beam controller, which ultimately moves the beam from one of these dwell points to the next. The sequence of dwell points may be generated according to a fixed pattern, for example a serpentine scan pattern, or the sequence may be an arbitrary pattern. The number of dwell points required will depend upon the size and composition of the defect and upon the size of the ion beam used for the repair.

In step 226, based upon the elevational data for the area within the repair box, a preliminary ion beam dosage for each dwell point within defect is calculated. In a preferred embodiment, the topographical data is divided into ranges or “height steps” with limits on the highest and lowest heights to be repaired. The height limits need not correlate exactly with the elevational data from the SPM scan. For example, for a given type of defect the operator might specify a minimum that is slightly above the zero-defect “floor” in order to ensure that the area is not milled too deeply. These maximum and minimum height limits and the number and size of each height steps desired are entered into the system through the software's graphical user interface. The total height of the defect is then broken down into the desired number of height steps with each step up or down comprising the same difference in height measurement. Any number of height steps can be used-but too few will result in poor repair quality and too many will require more time to process. For a typical quartz bump repair, sixteen height steps would be used.

Once the height steps have been calculated, a discrimination is performed based upon the topographical data to assign each dwell point within the repair box to the appropriate height step. Based upon the height step for each dwell point and upon the etch rate for the defect material, a preliminary ion dose is then assigned to each point. For example, all dwell points assigned to the highest height step will receive a full dose while dwell points assigned to lower height steps will receive an appropriate percentage of a full dose. The etch rate can be determined experimentally before the repair process is instituted or known etch rates for the defect material found in literature can be applied.

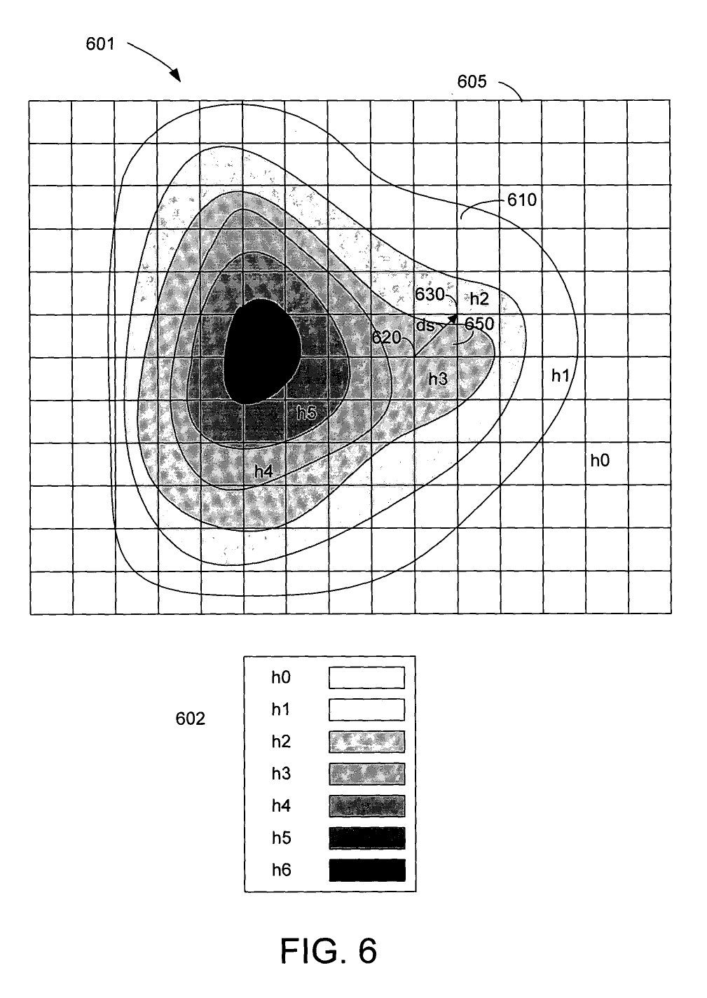

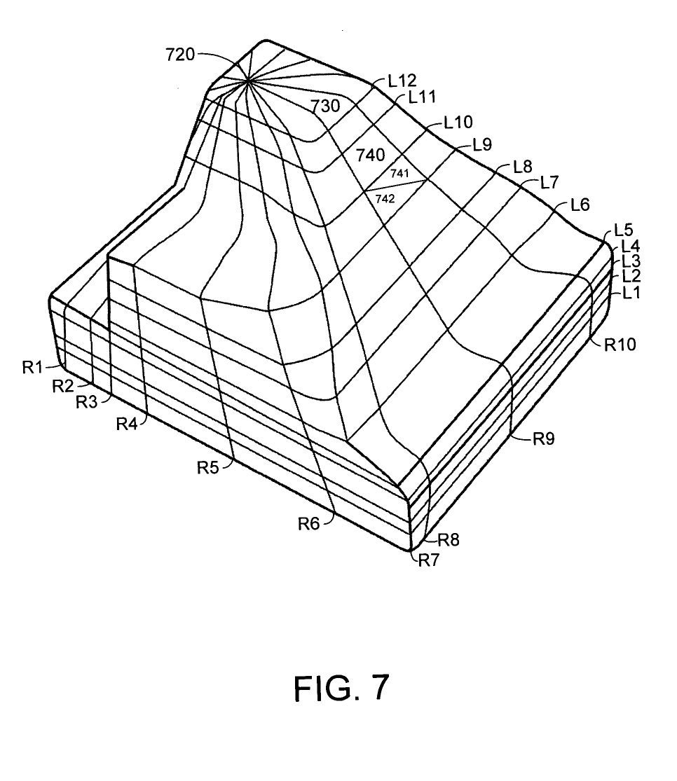

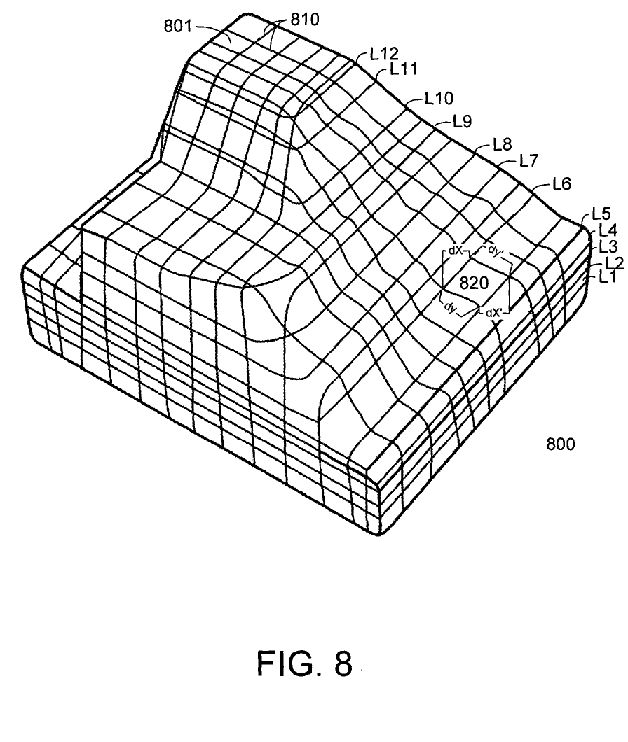

Optional steps 228 and 230, which consider the effect of the angle of incidence of the beam on the etching rate, can be used to produce a better surface on the mask. In step 228, the surface angle at each dwell point is calculated. This calculation is desired because the etch rate for a given material is dependent on the angle of the ion beam to the material. In one embodiment, the actual surface slope at each dwell point is approximated from the topographical data by comparing the elevation at SPM pixels within the dwell point to the elevation of surrounding pixels. Since an SPM typically has a higher resolution that an FIB system, there may be more than one SPM pixel located within a given dwell point. In that case, a best approximate elevation could be used in the slope calculations. Additional methods of slope calculation are shown in FIG. 6, FIG. 7, and FIG. 8 discussed below.

In step 230, a dose correction based upon the surface slope at each dwell point is applied to the preliminary ion dose for each dwell point. Etch rate (also referred to as sputtering yield) typically increases with the ion beam angle of incidence up to a certain angle, then decreases. Failure to correct for surface angle, which can also be referred to as sidewall slope, will typically result in a low quality (non-planar) repair since the etch rate will be higher than expected at some surface angles and lower at others (and thus too much material will be etched away at some points and too little etched at other points). Appropriate sidewall slope correction values for given angles and materials are well known and described, for example, in A. Benninghoven, Secondary Ion Mass Spectrometry, John Wiley & Sons, Inc., pages 193-195 (1987). The correction values can be stored in the form of a lookup table. The correction from the lookup table is applied to the preliminary ion beam dose for each dwell point to calculate the final ion beam dose.

In step 232, the ion beam is directed to repair the defect. Each dwell point within the defect area receives the appropriate final ion beam dose and the end result is a flat (non-defect) surface. A typical system would use a beam current of 5 pA to 100 pA, a beam energy of 30 keV, a beam diameter of 5 nm to 50 nm, and a dwell point spacing of 10 nm. Skilled persons can readily determine appropriate beam characteristics to suit a particular application. In a preferred embodiment, the final ion beam dose to be delivered to each dwell point is divided into multiple passes or loops around the repair area, with relatively short dwell times during each loop. Leaving the beam on each point for an extended period of time can produce a rough surface and exacerbate redeposition of sputtered material. For focused ion beams, dwell times of less than 1 μs are preferred, with dwell times of less than 500 ns more preferred. Dwell times of 100 ns are typical for non-contiguous points, but dwell times of up to 10 ms or much longer can be used. The ion beam is directed at each dwell point in sequence until a dwell point has received the appropriate final ion dose. That dwell point is then removed from the sequence of points, and the ion beam is directed to the next point in the sequence of points that was generated in step 225. In another preferred embodiment, the ion beam can be initially directed only at the highest defect points. On subsequent passes of the ion beam, the dwell point sequence can expand to cover lower defect points. In other words, the defect can be milled from the top down. The operator can select between different milling strategies by means of a software selectable toggle.

In step 234, once the defect repair is completed the system determines whether any other unrepaired defects remain on the workpiece. If so, the x and y coordinates for the next unrepaired defect area are retrieved by the FIB system and the system returns to step 219. Steps 219 to 234 are repeated until no unrepaired defects remain.

In one embodiment of the invention, the method described above can further include the steps of (i) scanning a selected portion of the substrate with the focused particle beam, and (ii) applying a clean-up gas, concurrent to the substrate scanning step, to remove a surface layer of the selected portion of the substrate for insuring high transmission of electromagnetic radiation by the selected portion of the substrate. In a preferred embodiment, the clean-up gas is a fluorine-based clean-up gas, more preferably xenon difluoride.

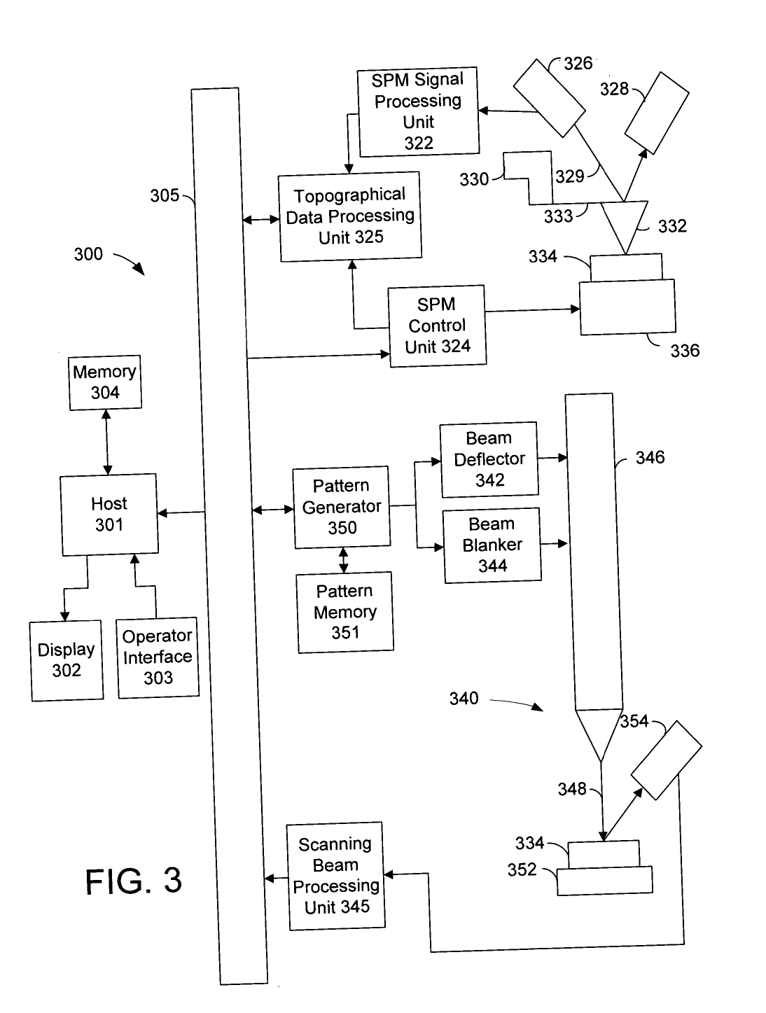

FIG. 3 depicts an embodiment of a system 300 of the present invention. The embodiment depicted in FIG. 3 comprises a scanning probe microscope system 320, a scanning beam system 340, a host computer 301, a display 302, an operator interface 303 (such as a keyboard and mouse) and a host interface 305. In some embodiments, scanning probe microscope system 320 and scanning beam system 340 could use separate host computers. Data could be transferred between the separate computers, for example, by storing data on removable media that is moved from one computer to another. In other embodiments, all or part of the functionality of host computer 301 can be replaced with one or more embedded computers.

Scanning probe microscope system 320 includes the physical hardware of the beam system, including tip 332, cantilever 333, workpiece 334, moveable stage 336, fixed support 330, laser source 328, laser beam 329, and detector 326. SPM control unit 324 operates moveable stage 336 and controls the positioning of work piece 334 under cantilever 332. SPM signal processing unit 322 receives the deflection data from detector. Topographical data processing unit 325 processes the data from SPM signal processing unit 322 and generates a three dimensional virtual topographical map of each defect area. This virtual topographical map is transferred to host computer 301 by way of host interface 305 and is stored in memory 304.

Scanning beam system 340 includes the physical hardware of the beam system, including an ion optical column 346 and a detector 354 for generating a signal corresponding to a characteristic of the surface at each point to which the beam is directed. Ion optical column 346 includes a beam source, lenses for focusing the beam, a beam deflector 342 for steering the beam, and a beam blanker 344 for interrupting the beam. The analog signals from detector 354 are converted into digital signals and subjected to signal processing by scanning beam signal processing unit 345. The resulting digital signal is used by host 301, in coordination with signals from beam deflector 342, to display an image of workpiece 334 on display 302. The virtual topographic map is then used to generate a two dimensional topographical bitmap of workpiece 334 on display 302 (with the two dimensional topographical bitmap superimposed on the scanning beam image of the defect area).

By way of input from operator interface 303 and the calculations discussed above, the repair area is communicated to pattern generator 350, which generates a sequence of dwell points. This sequence of dwell points is optionally stored in pattern memory 351, which can be part of pattern generator 350 or external to pattern generator 350. Based upon the sequence of dwell points supplied by pattern generator 350, beam deflector 342 directs the scanning beam 348 to the appropriate point on workpiece 334. When a raster scanning pattern is used, beam blanker 344 can be used when the beam is returned to the starting point for the next line.

FIG. 4A shows an example of a topographical data bitmap 400 of a defect area superimposed upon a partial display of an FIB image 410 by using only the x and y coordinates from the inspection system. In this example, as is typically the case, topographical data bitmap 400 is not properly aligned with FIB image 410. This is because the x and y coordinates from the inspection system cannot be perfectly matched to the x and y coordinates of the FIB system. The inspection data file (e.g., generated by a mask inspection tool, such as those manufactured by KLA-Tencor Corporation, San Jose, Calif.) is used to navigate to the defect locations both on the FIB and the SPM. Even with the laser interferometer controlled stage of the FIB system and its submicron precision and accuracy, the ability to position the defect beneath the ion beam will be limited by the precision and accuracy of the inspection system. Also, the ability to correct for rotation, scaling, and orthogonality on both systems and the ability to match these corrections between the inspection and FIB systems will limit the accuracy of positioning the defects beneath the ion beam to a few microns. Topographical data bitmap 400 comprises the outline of non-defect surface features 402′ such as chromium lines, and defect 401′. The remaining area within topographical data bitmap 400 comprises substrate 404′, such as quartz grooves between the chromium lines. Topographical data bitmap 400 includes both defect 401′ and enough non-defect area to provide landmarks to allow the operator to align the images. FIB image 410 comprises only non-defect surface features 402, such as chromium lines, and substrate 404, such as quartz grooves between the chromium lines. Defect 401′ is not necessarily visible in FIB image 410. In this example, non-defect surface features 402′ are not aligned with non-defect surface features 402. As a result, for any repair initiated at this point, the FIB system would not be directed at the defect area and any milling would result in actual damage to the photomask rather than repair of defect 401′.

FIG. 4B shows an example of a topographical data bitmap 400 of a defect area accurately superimposed upon the display of an FIB image 410. In a preferred embodiment, the operator will move the topographical data bitmap 400 by use of a computer mouse and cursor (or any other method) in order to accurately align the two images. After this final alignment, non-defect surface features 402′ are aligned with non-defect surface features 402 and any subsequent FIB repair would be directed at the precise location of the defect 401′.

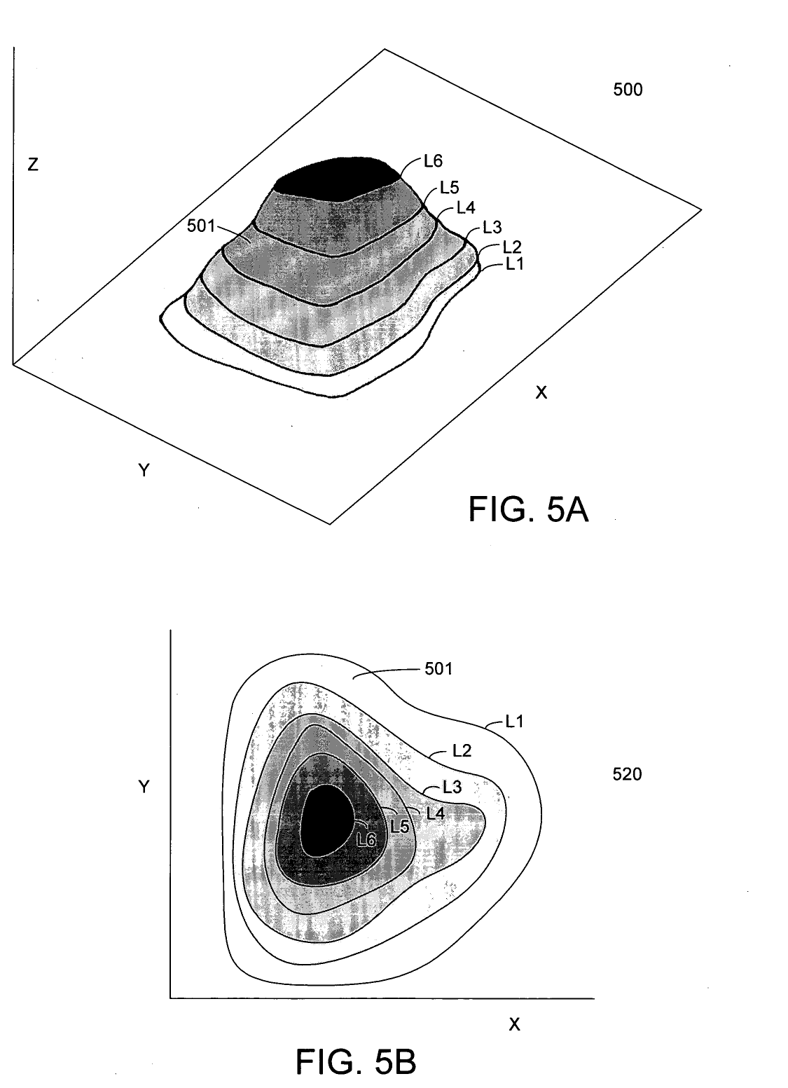

FIG. 5A shows a representation of a three-dimensional virtual topographical map 500 of a defect 501. Virtual topographical map 500 is comprised of lines representing the defect's dimensions in the x and y and the elevation of the various points within the defect as measured by the SPM scan. Elevational lines L1 through L6 show the different elevations of defect 501, in much the same way that elevation is indicated a typical topographical map of the earth's surface. Such a representation can be displayed on any suitable display device, such as a conventional CRT or flat panel monitor.

FIG. 5B shows a representation of a two-dimensional topographical bitmap 520 of defect 501. Two-dimensional topographical bitmap 520 is comprised of lines representing the defect's dimensions in the x and y and the elevation of the various points within the defect as measured by the SPM scan. Again, elevational lines L1 through L6 indicate different elevations even though the bitmap only shows the x and y dimensions. Such a representation can be displayed on any suitable display device, such as a conventional CRT or flat panel monitor.

FIG. 6 shows a representation of a three-dimensional virtual topographical map 601 of a defect 610 illustrating one method of calculating slope angle at each dwell point within the defect area. Virtual topographical map 601 is created by using of a series of data points representing the defect's dimensions in the x and y and the elevation of the various points within the defect as measured by the SPM scan (z). Using the x-y-z data for each point, known algorithms can be used to define a contour (closed curves in XY space) along which a given height is maintained. In the resulting virtual topographical map 601, the defect is broken down into various height steps h1 through h6 (with h0 representing the zero-defect floor) based upon the elevation of the various points within the defect. Legend 602 shows the different shading associated with each height step in virtual topographical map 610. Repair grid 605 is then superimposed over the contour plot. The dwell points (discussed above) that will be used to repair the defect are each assigned to a specific height step h1 through h6. For each dwell point, the surface slope can be geometrically approximated by the ratio of the contour height interval or height step to the perpendicular displacement between the contours so that the slope for dwell points within repair grid 650=(h3−h2)/ds (where ds represents the distance between repair grid points 620 and 630).

FIG. 7 shows a representation of a three-dimensional topographical bitmap 700 illustrating another method of calculating slope angle at each dwell point within the defect area. Elevational lines L1 through L12 show the different elevations of defect 701. Center point 720 is defined as the highest point in the three-dimensional topographical bitmap of the defect. Equally spaced radiating lines R1 through R10 are drawn from center point 720 to the outside edge of the defect. The intersection of radiating lines R1 through R10 with elevational lines L1 through L12 divides the surface of the three-dimensional topographical bitmap into a number of triangles 730 (at the top elevational layer 750) and a number of trapezoids 740 (along the sidewalls 760). The three points of each triangle 730 at the top layer serve to define a plane. By calculating the angle between the horizontal plane and each of the planes defined by the triangles at the top elevational level, a surface slope value can be assigned to all dwell points within each triangle 730.

Along the sidewalls of three-dimensional topographical bitmap 700, the intersection of elevational lines 710 with the radiating lines 712 divides the remainder of the bitmap surface into a number of trapezoids 740. Each trapezoid is further divided along its diagonal into two triangles 741 and 742. As described above, the three points of each of these sidewall triangles serve to define a plane. By calculating the angle between the horizontal plane and each of the planes defined by the sidewall triangles, a surface slope value can be assigned to all dwell points within each sidewall triangle.

FIG. 8 shows a representation of a three-dimensional topographical bitmap 800 illustrating another method of calculating slope angle at each dwell point within the defect area. According to this method, the surface area of the three-dimensional topographical bitmap is divided by grid lines 810 in the x-y horizontal plane. Grid lines intersect with elevational lines L1 through L12, dividing the surface into a number of trapezoids 820. For each trapezoid, an X value is calculated as the average of the two dX values for the trapezoid (dX+dX′)/2, a Y value is calculated as the average of the two dY values for the trapezoid (dY+dY′)/2, and a Z value is calculated as the difference between the highest and lowest points within the trapezoid. The values of X, Y, and Z define a plane dXdYdZ. By calculating the angle between the horizontal plane and plane dXdYdZ, a surface slope value can be assigned to all dwell points within each trapezoid.

This application describes several novel features which may be used separately or in combination. The system of the present invention can be adapted for different purposes, and not all systems covered by the claims will meet every object of the invention or include every feature described herein.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

We claim as follows:

1. A method of repairing a defect in a photolithography mask, comprising:
obtaining topographical data on a defect using a scanning probe microscope;
transferring the topographical data to a charged particle beam system;
generating a topographical data image;
obtaining a charged particle beam image of the defect area;
superimposing the topographical data image over the charged particle beam image;
aligning visible features in the two images;
using the topographical data to determine appropriate charged particle beam dose to repair the defect; and
directing a charged particle beam at the defect.

2. The method of claim 1 in which the topographical data on the defect is used to generate a three-dimensional bitmap of the defect area.

3. The method of claim 1 in which the density of the topographical data image can be adjusted to make the image more transparent or less transparent.

4. The method of claim 1 in which using the topographical data to determine appropriate charged particle beam dose to repair the defect comprises:
determining the etch rate for the defect material;
generating a sequence of dwell points adequate to repair the defect;
determining the elevation of each dwell point from the topographical data;
assigning the dwell points with the maximum elevation a full charged particle beam dose sufficient to repair the dwell points;
assigning lower dwell points a proportionate percentage of the full charged particle beam dose;
determining the surface angle for each dwell point; and
applying a slope correction to the assigned beam dose for each dwell point.

5. The method of claim 4 further comprising dividing the maximum defect height into a number of height steps and assigning each dwell points to a height step based upon the elevation of each dwell point.

6. A method of repairing a bump defect in a phase shift photolithography mask, comprising:
obtaining topographical data on a bump defect using a scanning probe microscope;
transferring the topographical data to a charged particle beam system;
generating a topographical data image;
obtaining a charged particle beam image of the defect area;
superimposing the topographical data image over the charged particle beam image;
aligning visible features in the two images;
using the topographical data to determine appropriate charged particle beam dose to repair the defect; and
directing a charged particle beam at the defect.

7. The method of claim 6 in which the topographical data on the defect is used to generate a three-dimensional bitmap of the defect area.

8. The method of claim 6 in which the density of the topographical data image can be adjusted to make the image more transparent or less transparent.

9. The method of claim 6 in which using the topographical data to determine appropriate charged particle beam dose to repair the defect comprises:
determining the etch rate for the defect material;
generating a sequence of dwell points adequate to repair the defect;
determining the elevation of each dwell point from the topographical data;
assigning the dwell points with the maximum elevation a full charged particle beam dose sufficient to repair the dwell points;
assigning lower dwell points a proportionate percentage of the full charged particle beam dose;
determining the surface angle for each dwell point; and
applying a slope correction to the assigned beam dose for each dwell point.

10. The method of claim 9 further comprising dividing the maximum defect height into a number of height steps and assigning each dwell points to a height step based upon the elevation of each dwell point.

11. A method of repairing a divot defect in a phase shift photolithography mask, comprising:
obtaining topographical data on a divot defect using a scanning probe microscope;
transferring the topographical data to a charged particle beam system;
generating a topographical data image;
obtaining a charged particle beam image of the defect area;
superimposing the topographical data image over the charged particle beam image;
aligning visible features in the two images;
using the topographical data to determine appropriate charged particle beam dose to repair the defect; and
directing a charged particle beam at the defect.

12. The method of claim 11 in which the topographical data on the defect is used to generate a three-dimensional bitmap of the defect area.

13. The method of claim 11 in which the density of the topographical data image can be adjusted to make the image more transparent or less transparent

14. A method of directing a charged particle beam system using topographical data from an SPM scan of a defect area comprising:
generating a topographical data image of the defect area from the topographical data from an SPM scan;
superimposing the topographical data image over a charged particle beam image of the defect area; and
adjusting the position of the images to accurately align the topographical data image with the charged particle beam image.

15. The method of claim 14 in which area scanned by the SPM and by the charged particle beam system includes distinct non-defect features.

16. The method of claim 14 in which in which the density of the topographical data image can be adjusted to make the image more transparent or less transparent.

17. The method of claim 15 in which in which the density of the topographical data image can be adjusted to make the image more transparent or less transparent.

18. A method of using topographical data to calculate the charged particle beam dose for each dwell point within a bump defect comprising:
determining the etch rate for the defect material;
generating a sequence of dwell points adequate to repair the defect;
determining the elevation of each dwell point from the topographical data;
assigning the dwell points with the maximum elevation a full charged particle beam dose sufficient to repair the dwell points;
assigning lower dwell points a proportionate percentage of the full charged particle beam dose;
determining the surface angle for each dwell point; and
applying a slope correction to the assigned beam dose for each dwell point.

19. The method of claim 18 further comprising dividing the maximum defect height into a number of height steps and assigning each dwell points to a height step based upon the elevation of each dwell point.

20. A system for repairing a defect in a photolithography mask, comprising:
a means for obtaining topographical data on a defect;
a means for transferring the topographical data to a charged particle beam system;
a means for generating a topographical data image;
a means for obtaining a charged particle beam image of the defect area;
a means for superimposing the topographical data image over the charged particle beam image;
a means for aligning visible features in the two images;
a means for using the topographical data to determine appropriate charged particle beam dose to repair the defect; and
a means for directing a charged particle beam at the defect.

21. An apparatus for repairing a defect in a photolithography mask, comprising:
a device for determining topological features of a defect area;
a device for processing topological data, generating a topographical image of a defect area, and storing the data and the topographical image in memory;
a display unit for displaying the topographical image;
a charged particle beam system having a charged particle source for emitting a charged particle beam, an optical system for focusing the charged particle beam, a computer controlled beam deflector to position the charged particle beam, a secondary charged particle detector for detecting secondary charged particles and outputting a corresponding signal, and a display unit for displaying a charged particle beam image;
a processor for aligning the topographical image and the charged particle beam image, and for using the topographical data to control the charged particle beam.

22. The apparatus of claim 21 in which the device for determining topological features of a defect area is a scanning probe microscope.

23. The apparatus of claim 21 in which the charged particle beam system is a focused ion beam system.

24. The apparatus of claim 21 in which using the topographical data to control the beam comprises:
generating a sequence of dwell points adequate to repair the defect;
determining the elevation of each dwell point from the topographical data;
assigning the dwell points with the maximum elevation a full charged particle beam dose sufficient to repair the dwell points;
assigning lower dwell points a proportionate percentage of the full charged particle beam dose;
determining the surface angle for each dwell point; and
applying a slope correction to the assigned beam dose for each dwell point.
